(19) United States
(12) Patent Application Publication
(10) Pub. No.: US 2026/0071325 A1
(43) Pub. Date: Mar. 12, 2026

(54) METHOD OF MANUFACTURING SEMICONDUCTOR DEVICE

(71) Applicant: Kioxia Corporation, Tokyo (JP)

(72) Inventors: Akito HIRANO, Yokkaichi (JP); Masakazu TANUMA, Yokohama (JP); Hiroshi MATSUBA, Fujisawa (JP); Kenichiro TORATANI, Yokkaichi (JP); Masaya NAKATA, Yokkaichi (JP); Yu SAITO, Yokkaichi (JP)

(73) Assignee: Kioxia Corporation, Tokyo (JP)

(21) Appl. No.: 19/060,028

(22) Filed: Feb. 21, 2025

(30) Foreign Application Priority Data
Sep. 12, 2024 (JP) 2024-158544

(51) Int. Cl. C23C 16/448; H01L 21/02; H01L 21/324; H10B 12/00

(52) U.S. Cl. CPC C23C 16/4485; H10B 12/05; H10P 14/24; H10P 14/3434; H10P 95/90

(57) ABSTRACT

In one embodiment, a method of manufacturing a semiconductor device includes preparing a first liquid including a first element that is a metal element or silicon, and a predetermined element that is a metal element or silicon and different from the first element. The method further includes generating a first gas including the first element and the predetermined element from the first liquid. The method further includes forming a first film including the first element and the predetermined element on a substrate by using the first gas.

### CROSS-REFERENCE TO RELATED APPLICATIONS

This application is based upon and claims the benefit of priority from the prior Japanese Patent Application No. 2024-158544, filed on Sep. 12, 2024, the entire contents of which are incorporated herein by reference.

### FIELD

Embodiments described herein relate to a method of manufacturing a semiconductor device.

### BACKGROUND

When a film including a plurality of elements (for example, two or more metal elements) is to be formed, a problem lies in determining how to form the film. For example, the problem is what kind of material is used to form the film.

### BRIEF DESCRIPTION OF THE DRAWINGS

FIG. 1 is a schematic diagram illustrating the configuration of a semiconductor manufacturing apparatus of a first embodiment;

FIGS. 2A and 2B are cross-sectional views illustrating a method of manufacturing a semiconductor device of the first embodiment;

FIG. 3 is a schematic diagram illustrating the configuration of a semiconductor manufacturing apparatus of a comparative example of the first embodiment;

FIGS. 4A and 4B are cross-sectional views illustrating a method of manufacturing a semiconductor device of the comparative example of the first embodiment;

FIG. 5 is a schematic diagram illustrating the configuration of a semiconductor manufacturing apparatus of a modification of the first embodiment;

FIG. 6 is a circuit diagram illustrating the configuration of a semiconductor device of a second embodiment;

FIG. 7 is a cross-sectional view illustrating the structure of the semiconductor device of the second embodiment; and

FIGS. 8 to 10 are cross-sectional views illustrating a method of manufacturing the semiconductor device of the second embodiment.

### DETAILED DESCRIPTION

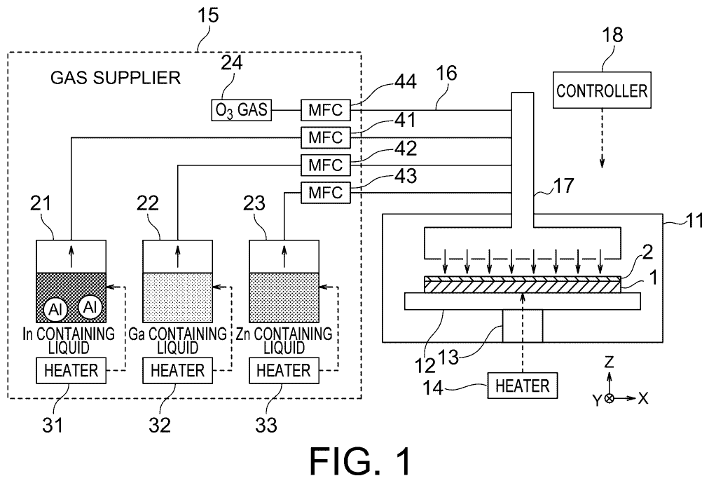

Embodiments will now be explained with reference to the accompanying drawings. In FIGS. 1 to 10, identical components are denoted by the same reference sign, and duplicate description thereof is omitted.

In one embodiment, a method of manufacturing a semiconductor device includes preparing a first liquid including a first element that is a metal element or silicon, and a predetermined element that is a metal element or silicon and different from the first element. The method further includes generating a first gas including the first element and the predetermined element from the first liquid. The method further includes forming a first film including the first element and the predetermined element on a substrate by using the first gas.

### First Embodiment

FIG. 1 is a schematic diagram illustrating the configuration of a semiconductor manufacturing apparatus of a first embodiment. The semiconductor manufacturing apparatus of the present embodiment is, for example, a chemical vapor deposition (CVD) apparatus, and more specifically, an atomic layer deposition (ALD) apparatus.

The semiconductor manufacturing apparatus of the present embodiment includes a chamber 11, a stage 12, a shaft 13, a heater 14, a gas supplier 15, a plurality of gas flow paths 16, a shower head 17, and a controller 18. The gas supplier 15 includes tanks 21 to 23, a gas source 24, heaters 31 to 33, and mass flow controllers (MFCs) 41 to 44.

FIG. 1 illustrates an X direction, a Y direction, and a Z direction orthogonal to each other. In the specification, the +Z direction is an upward direction, and the −Z direction is a downward direction. The −Z direction may or may not be aligned with the direction of gravity. In the present embodiment, the X, Y, and Z directions are used to indicate directions in the chamber 11, for example.

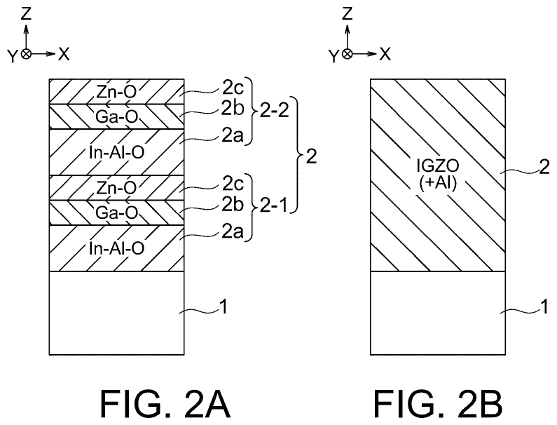

Further detail of the semiconductor manufacturing apparatus of the present embodiment will be described below with reference to FIG. 1. In the description, FIGS. 2A and 2B are referred as appropriate. FIGS. 2A and 2B are cross-sectional views illustrating a method of manufacturing a semiconductor device of the first embodiment.

### [Chamber 11]

The chamber 11 houses a substrate 1 to be processed. FIG. 1 illustrates processing of forming a film 2 on the substrate 1 in the chamber 11. The substrate 1 is, for example, a semiconductor substrate such as a silicon (Si) substrate. The film 2 is, for example, a CVD film formed by CVD. In the present embodiment, the substrate 1 is a semiconductor wafer, and the film 2 is an ALD film. The film 2 is an example of the first film.

The film 2 includes, for example, one or more elements among indium (In), gallium (Ga), zinc (Zn), tin (Sn), antimony (Sb), aluminum (Al), silicon (Si), titanium (Ti), zirconium (Zr), hafnium (Hf), niobium (Nb), tantalum (Ta), molybdenum (Mo), and tungsten (W). These elements are examples of a first element, a second element, a third element, and a predetermined element in the first film. The film 2 may further include oxygen (O).

The film 2 of the present embodiment is an oxide semiconductor film and for example, an IGZO film including indium, gallium, zinc, and oxygen. The film 2 of the present embodiment may further include aluminum. The film 2 is, for example, an IGZO film including aluminum as an impurity element. In these cases, indium, gallium, and zinc are each an example of the first, second, and third elements in the first film and an example of a metal element in the first film. In addition, aluminum is an example of the predetermined element in the first film and an example of the metal element in the first film.

The film 2 may be a film other than an IGZO film. For example, the film 2 may include one or more elements among indium, gallium, zinc, tin, aluminum, and silicon as component elements. In addition, the film 2 may include one or more elements among tin, antimony, aluminum, silicon, and niobium as impurity elements different from the component elements.

In the present embodiment, the substrate 1 is conveyed into the chamber 11, the film 2 is formed on the substrate 1 in the chamber 11, and thereafter, the substrate 1 is conveyed out of the chamber 11. The substrate 1 and the film 2 may be annealed outside the chamber 11 thereafter. For example, the film 2 may be formed in the chamber 11 as a multilayer film including a plurality of layers (refer to FIG. 2A) and may be annealed outside the chamber 11 to change from the multilayer film to an IGZO film (refer to FIG. 2B). Further detail of such processing will be described later.

### [Stage 12]

The stage 12 supports the substrate 1 in the chamber 11. In FIG. 1, the substrate 1 is placed on the upper face of the stage 12 such that the front surface of the substrate 1 faces in the +Z direction and the back surface of the substrate 1 faces in the −Z direction.

### [Shaft 13]

The shaft 13 is attached to the lower face of the stage 12 and supports the stage 12. The shaft 13 may be configured to rotate the substrate 1 placed on the stage 12 as the stage 12 is rotated.

### [Heater 14]

The heater 14 heats the substrate 1 placed on the stage 12. This makes it possible to form the film 2 on the substrate 1 while the substrate 1 and the film 2 are kept at high temperature by the heater 14.

### [Gas Supplier 15]

The gas supplier 15 supplies one or more kinds of gasses into the chamber 11. In the present embodiment, the film 2 can be formed on the substrate 1 with these gasses. These gasses may include only a source gas of the film 2 or may include other gasses (for example, conveyance gas).

The tank 21 accumulates a liquid (In-containing liquid) containing indium. The tank 21 of the present embodiment accumulates an In-containing liquid that is liquid at room temperature. The In-containing liquid is, for example, a triethylindium (TEIn) liquid. The heater 31 generates a gas (In-containing gas) containing indium from the In-containing liquid by heating the In-containing liquid in the tank 21. The In-containing gas is, for example, a TEIn gas. The In-containing gas is introduced into the chamber 11 through the MFC 41. The MFC 41 adjusts circulation and the flow rate of the In-containing gas. Each In-containing layer 2a illustrated in FIG. 2A is formed by using the In-containing gas. The In-containing liquid is an example of the first liquid, the In-containing gas is an example of the first gas, each In-containing layer 2a is an example of a first layer. The In-containing liquid may contain an In compound material other than TEIn.

The In-containing liquid of the present embodiment contains aluminum together with indium. The In-containing liquid of the present embodiment is, for example, a TEIn liquid containing trimethylaluminum (TMAI) as an impurity compound and is generated by adding TMAI as a dopant to the TEIn liquid. In the present embodiment, the In-containing gas is a gas containing indium and aluminum, and each In-containing layer 2a is a layer containing indium and aluminum. The In-containing liquid may contain an Al compound other than TMAI.

The In-containing liquid of the present embodiment contains indium and aluminum, and aluminum has a greater bond energy with oxygen and a smaller free energy on the Ellingham diagram than indium. Thus, it is expected that the surface adsorption rate of aluminum is greater than the surface adsorption rate of indium and Al compound molecules in the In-containing gas adsorb onto the surface of the substrate 1 more quickly than In compound molecules in the In-containing gas. This makes it possible to increase the concentration of aluminum in the film 2 even when the concentration of aluminum in the In-containing liquid is low.

For example, in TEIn (In(C₂H₅)₃) liquid containing TMAI (Al(CH₃)₃), the In concentration is higher than the Al concentration. When a gas generated from such a TEIn liquid and O₃ gas) to be described later are supplied onto the surface of the substrate 1, In(OH)₃ is formed on the surface of the substrate 1. In this case, Al(CH₃)₃ adsorbs onto the surface of the substrate 1, on which In(OH)₃ is formed, more quickly than In(C₂H₅)₃. The reason is that the activation energy (0.58 eV) of the following chemical formula (1) is lower than the activation energy (0.84 eV) of the following 25 chemical formula (2).

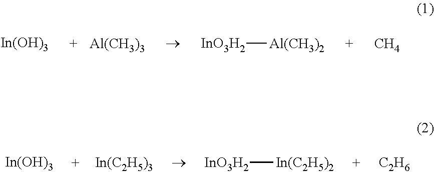

In the present embodiment, the concentration (g/L) of aluminum in the In-containing liquid is lower than the concentration (g/L) of indium in the In-containing liquid. As a result of study, it was found that the concentration of aluminum in the film 2 significantly increases when the concentration of aluminum in the In-containing liquid is increased to 50 ppb or higher. It was also found that it is more desirable to increase the concentration of aluminum in the In-containing liquid to 100 ppb or higher.

The tank 22 accumulates a liquid (Ga-containing liquid) containing gallium. The tank 22 of the present embodiment accumulates a Ga-containing liquid that is liquid at room temperature. The Ga-containing liquid is, for example, a triethylgallium (TEGa) liquid. The heater 32 generates a gas (Ga-containing gas) containing gallium from the Ga-containing liquid by heating the Ga-containing liquid in the tank 22. The Ga-containing gas is, for example, a TEGa gas. The Ga-containing gas is introduced into the chamber 11 through the MFC 42. The MFC 42 adjusts circulation and the flow rate of the Ga-containing gas. Each Ga-containing layer 2b illustrated in FIG. 2A is formed by using the Ga-containing gas. The Ga-containing liquid is an example of a second liquid, the Ga-containing gas is an example of a second gas, and each Ga-containing layer 2b is an example of a second layer. The Ga-containing liquid may contain a Ga compound material other than TEGa.

The tank 23 accumulates a liquid (Zn-containing liquid) containing zinc. The tank 23 of the present embodiment accumulates a Zn-containing liquid that is liquid at room temperature. The Zn-containing liquid is, for example, a diethylzinc (DEGa) liquid. The heater 33 generates a gas (Zn-containing gas) containing zinc from the Zn-containing liquid by heating the Zn-containing liquid in the tank 23. The Zn-containing gas is, for example, a DEZn gas. The Zn-containing gas is introduced into the chamber 11 through the MFC 43. The MFC 43 adjusts circulation and the flow rate of the Zn-containing gas. Each Zn-containing layer 2c illustrated in FIG. 2A is formed by using the Zn-containing gas. The Zn-containing liquid is an example of a third liquid, the Zn-containing gas is an example of a third gas, and each Zn-containing layer 2c is an example of a third layer. The Zn-containing liquid may contain a Zn compound material other than DEZn.

The gas source 24 supplies a gas (O-containing gas) containing oxygen. The gas source 24 may be provided in the gas supplier 15 or may be provided outside the gas supplier 15. The O-containing gas is, for example, an ozone (03) gas. The O-containing gas is introduced into the chamber 11 through the MFC 44. The MFC 44 adjusts circulation and the flow rate of the O-containing gas. Each In-containing layer 2a, each Ga-containing layer 2b, and each Zn-containing layer 2c illustrated in FIG. 2A are formed by using the O-containing gas. In the present embodiment, each In-containing layer 2a is an In—Al—O layer containing indium, aluminum, and oxygen, each Ga-containing layer 2b is a Ga—O layer containing gallium and oxygen, and each Zn-containing layer 2c is a Zn—O layer containing zinc and oxygen.

Hereinafter, processing of introducing the In-containing gas into the chamber 11 is referred to as “In introduction processing”, processing of introducing the Ga-containing gas into the chamber 11 is referred to as “Ga introduction processing”, processing of introducing the Zn-containing gas into the chamber 11 is referred to as “Zn introduction processing”, and processing of introducing the O-containing gas into the chamber 11 is referred to as “O introduction processing”.

The film 2 of the present embodiment is formed by alternately repeating the In introduction processing, the Ga introduction processing, and the Zn introduction processing. For example, each cycle of the processing of forming the film 2 is executed by sequentially performing the In introduction processing, the O introduction processing, the Ga introduction processing, the O introduction processing, the Zn introduction processing, and the O introduction processing, and the processing of forming the film 2 is repeated through a plurality of cycles. In each cycle, purge processing is performed after end of the In introduction processing, after end of the first O introduction processing, after end of the Ga introduction processing, after end of the second O introduction processing, after end of the Zn introduction processing, and after end of the third O introduction processing. The In introduction processing, the Ga introduction processing, and the Zn introduction processing are examples of first processing, second processing, and third processing, respectively. In each cycle, the In introduction processing, the Ga introduction processing, and the Zn introduction processing may be performed in an order different from the above-described order, and two times or more of the In introduction processing, two times or more of the Ga introduction processing and/or two times or more of the Zn introduction processing may be performed.

In the present embodiment, the film 2 illustrated in FIG. 2A is formed by alternately repeating the In introduction processing, the Ga introduction processing, and the Zn introduction processing. Through a plurality of cycles of processing, the film 2 is formed to include a plurality of multilayer films. FIG. 2A illustrates a multilayer film 2-1 and a multilayer film 2-2 as examples of these multilayer films. The multilayer film 2-1 is formed on the substrate 1 through the first cycle. The multilayer film 2-2 is formed on the multilayer film 2-1 through the second cycle.

The multilayer films 2-1 and 2-2 each include an In-containing layer 2a, a Ga-containing layer 2b, and a Zn-containing layer 2c sequentially stacked in the Z direction. For example, the In-containing layer 2a is formed by the In introduction processing and the first O introduction processing in each cycle, the Ga-containing layer 2b is formed by the Ga introduction processing and the second O introduction processing in each cycle, and the Zn-containing layer 2c is formed by the Zn introduction processing and the third O introduction processing in each cycle.

In the present embodiment, the film 2 illustrated in FIG. 2A is formed in the chamber 11, and thereafter, the film 2 is annealed outside the chamber 11. As a result, the film 2 changes to the IGZO film illustrated in FIG. 2B. In the present embodiment, a plurality of films such as the film 2 are formed on the substrate 1, and thereafter, the substrate 1 is divided (diced) into a plurality of chips, and accordingly, the semiconductor device of the present embodiment is manufactured from the substrate 1.

In the present embodiment, indium, gallium, zinc, and aluminum are examples of the first element, the second element, the third element, and the predetermined element, respectively. However, the first element may be an element other than indium, the second element may be an element other than gallium, the third element may be an element other than zinc, and the predetermined element may be an element other than aluminum. In this case, it is desirable that the predetermined element has a greater bond energy with oxygen and/or a smaller free energy on the Ellingham diagram than the first element. This makes it possible to make the surface adsorption rate of the predetermined element greater than the surface adsorption rate of the first element. The film 2 may not include the second element and the third element. Moreover, the film 2 may not include the third element, may include the second and third elements, or may include the fourth to N-th elements (N is an integer of four or greater) together with the first to third elements.

### [Gas Flow Path 16]

Each gas flow path 16 couples the gas supplier 15 and the shower head 17. The semiconductor manufacturing apparatus of the present embodiment includes a gas flow path 16 (In-containing gas flow path) between the tank 21 and the shower head 17, a gas flow path 16 (Ga-containing gas flow path) between the tank 22 and the shower head 17, a gas flow path 16 (Zn-containing gas flow path) between the tank 23 and the shower head 17, and a gas flow path 16 (O-containing gas flow path) between the gas source 24 and the shower head 17.

The In-containing gas, the Ga-containing gas, the Zn-containing gas, and the O-containing gas are supplied to the shower head 17 through the In-containing gas flow path, the Ga-containing gas flow path, the Zn-containing gas flow path, and the O-containing gas flow path, respectively. The MFCs 41, 42, 43, and 44 are provided on the In-containing gas flow path, the Ga-containing gas flow path, the Zn-containing gas flow path, and the O-containing gas flow path, respectively.

### [Shower Head 17]

The shower head 17 supplies a gas from each gas flow path 16 into the chamber 11. As illustrated in FIG. 1, the shower head 17 is disposed above the stage 12 in the chamber 11. Accordingly, the gasses sprayed from the shower head 17 reach the surface of the substrate 1 on the stage 12. As a result, the film 2 is formed on the surface of the substrate 1.

### [Controller 18]

The controller 18 controls various kinds of operation of the semiconductor manufacturing apparatus of the present embodiment. The controller 18 controls, for example, vertical movement operation of the stage 12, operation of the heater 14, and operation of the gas supplier 15.

The controller 18 operates the heater 31 to raise the temperature of the In-containing liquid in the tank 21 to a predetermined temperature. This makes it possible to vaporize the In-containing liquid into the In-containing gas. The temperature of the In-containing liquid is desirably set to a temperature that is preferable for vaporizing the In-containing liquid into the In-containing gas. Such a preferable temperature can be determined from, for example, the vapor pressure curve of the In-containing liquid. The controller 18 adjusts the temperature of the In-containing liquid in the tank 21 to, for example, 30 to 50° C.

Similarly, the controller 18 operates the heater 32 to raise the temperature of the Ga-containing liquid in the tank 22 to a predetermined temperature. This makes it possible to vaporize the Ga-containing liquid into the Ga-containing gas. The temperature of the Ga-containing liquid is desirably set to a temperature that is preferable for vaporizing the Ga-containing liquid into the Ga-containing gas. Such a preferable temperature can be determined from, for example, the vapor pressure curve of the Ga-containing liquid. The controller 18 adjusts the temperature of the Ga-containing liquid in the tank 22 to, for example, 30 to 50° C.

Similarly, the controller 18 operates the heater 33 to raise the temperature of the Zn-containing liquid in the tank 23 to a predetermined temperature. This makes it possible to vaporize the Zn-containing liquid into the Zn-containing gas. The temperature of the Zn-containing liquid is desirably set to a temperature that is preferable for vaporizing the Zn-containing liquid into the Zn-containing gas. Such a preferable temperature can be determined from, for example, the vapor pressure curve of the Zn-containing liquid. The controller 18 adjusts the temperature of the Zn-containing liquid in the tank 23 to, for example, 30 to 50° C.

The controller 18 operates the heater 14 to raise the temperatures of the substrate 1 and the film 2 on the stage 12 to a predetermined temperature. This makes it possible to form the film 2 at a preferable temperature. The controller 18 adjusts the temperatures of the substrate 1 and the film 2 on the stage 12 to, for example, 200 to 300° C.

As described above, the semiconductor manufacturing apparatus of the present embodiment forms the film 2 (IGZO film) containing aluminum by using the In-containing liquid containing aluminum. This makes it possible to form the film 2 without preparing an Al-containing liquid in addition to the In-containing liquid, and thus it is possible to simplify materials, processes, instruments, and the like for forming the film 2. Moreover, it is possible to form the film 2 without introducing an Al-containing gas into the chamber 11 in addition to the In-containing gas, and thus it is possible to perform the processing of forming the film 2 in a short time and with fewer cycles. In addition, it is possible to increase the concentration of aluminum in the film 2 even when the concentration of aluminum in the In-containing liquid is low as described above, which makes it possible to achieve in-situ and high-concentration aluminum doping. In this manner, the present embodiment makes it possible to excellently form the film 2 containing a plurality of elements.

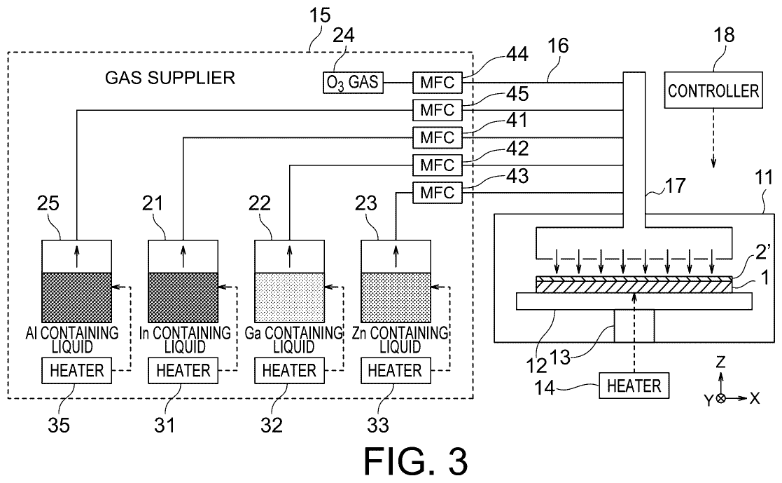

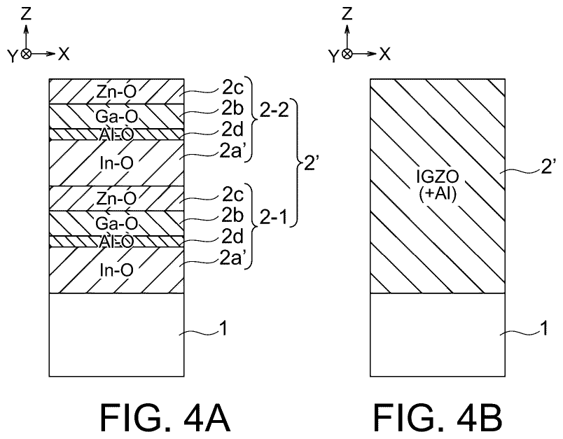

FIG. 3 is a schematic diagram illustrating the configuration of a semiconductor manufacturing apparatus of a comparative example of the first embodiment. FIGS. 4A and 4B are cross-sectional views illustrating a method of manufacturing a semiconductor device of the comparative example of the first embodiment.

The semiconductor manufacturing apparatus (FIG. 3) of the present comparative example has the same configuration as the semiconductor manufacturing apparatus (FIG. 1) of the first embodiment. However, the gas supplier 15 of the present comparative example includes a tank 25, a heater 35, and a MFC 45 in addition to the constituent components illustrated in FIG. 1. In the present comparative example, a film 2′ is formed on the substrate 1 instead of the film 2.

The tank 25 accumulates a liquid (Al-containing liquid) containing aluminum. The tank 25 of the present comparative example accumulates an Al-containing liquid that is liquid at room temperature. The heater 35 generates a gas (Al-containing gas) containing aluminum from the Al-containing liquid by heating the Al-containing liquid in the tank 25. The Al-containing gas is introduced into the chamber 11 through the MFC 45. The MFC 45 adjusts circulation and the flow rate of the Al-containing gas. Each Al-containing layer 2d illustrated in FIG. 4A is formed by using the Al-containing gas. In the present comparative example, the In-containing liquid in the tank 21 does not contain aluminum.

As illustrated in FIG. 3, the semiconductor manufacturing apparatus of the present comparative example includes a gas flow path 16 (Al-containing gas flow path) between the tank 25 and the shower head 17. The Al-containing gas is supplied to the shower head 17 through the Al-containing gas flow path. The MFC 45 is provided on the Al-containing gas flow path.

Hereinafter, processing of introducing the Al-containing gas into the chamber 11 is referred to as “Al introduction processing”.

In the present comparative example, the film 2′ illustrated in FIG. 4A is formed by alternately repeating the In introduction processing, the Al introduction processing, the Ga introduction processing, and the Zn introduction processing. Through a plurality of cycles of processing, the film 2′ is formed to include a plurality of multilayer films. FIG. 4A illustrates the multilayer film 2-1 and the multilayer film 2-2 as examples of these multilayer films.

The multilayer films 2-1 and 2-2 each include an In-containing layer 2a′, an Al-containing layer 2d, a Ga-containing layer 2b, and a Zn-containing layer 2c sequentially stacked in the Z direction. In the present comparative example, the In-containing layer 2a′ is an In—O layer containing indium and oxygen, and the Al-containing layer 2d is an Al—O layer containing aluminum and oxygen.

In the present comparative example, the film 2′ illustrated in FIG. 4A is formed in the chamber 11, and thereafter, the film 2′ is annealed outside the chamber 11. As a result, the film 2′ changes to an IGZO film illustrated in FIG. 4B. In the present embodiment, a plurality of films such as the film 2′ are formed on the substrate 1, and thereafter, the substrate 1 is divided (diced) into a plurality of chips, and accordingly, the semiconductor device of the present comparative example is manufactured from the substrate 1.

In the present comparative example, the Al-containing liquid is prepared in addition to the In-containing liquid to form the film 2′, and thus the materials, processes, instruments, and the like for forming the film 2′ are more complex. Furthermore, the Al-containing gas is introduced into the chamber 11 in addition to the In-containing gas to form the film 2′, and thus the processing of forming the film 2′ takes a long time and involves many cycles. However, the present embodiment makes it possible to form the film 2 while suppressing these problems.

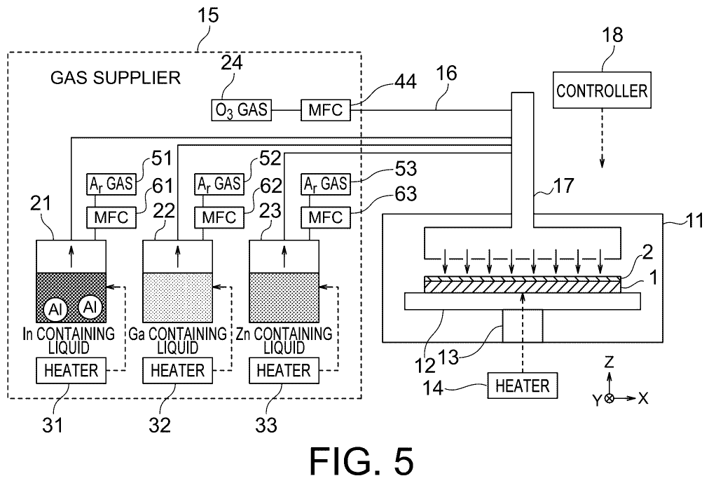

FIG. 5 is a schematic diagram illustrating the configuration of a semiconductor manufacturing apparatus of a modification of the first embodiment.

The semiconductor manufacturing apparatus (FIG. 5) of the present modification has the same configuration as the semiconductor manufacturing apparatus (FIG. 1) of the first embodiment. However, the gas supplier 15 of the present modification includes gas sources 51 to 53 and MFCs 61 to 63 in place of the MFCs 41 to 43. In the present modification, as in the first embodiment, the film 2 is formed on the substrate 1 in the flow illustrated in FIGS. 2A and 2B.

The gas source 51 supplies, into the tank 21, a conveyance gas (for example, argon gas) for conveying the In-containing gas. The gas source 51 may be provided in the gas supplier 15 or may be provided outside the gas supplier 15. The conveyance gas is supplied into the tank 21 through the MFC 61 and introduced from the tank 21 into the chamber 11 together with the In-containing gas. The MFC 61 can adjust circulation and the flow rate of the In-containing gas by adjusting circulation and the flow rate of the conveyance gas.

The gas source 52 supplies, into the tank 22, a conveyance gas (for example, argon gas) for conveying the Ga-containing gas. The gas source 52 may be provided in the gas supplier 15 or may be provided outside the gas supplier 15. The conveyance gas is supplied into the tank 22 through the MFC 62 and introduced from the tank 22 into the chamber 11 together with the Ga-containing gas. The MFC 62 can adjust circulation and the flow rate of the Ga-containing gas by adjusting circulation and the flow rate of the conveyance gas.

The gas source 53 supplies, into the tank 23, a conveyance gas (for example, argon gas) for conveying the Zn-containing gas. The gas source 53 may be provided in the gas supplier 15 or may be provided outside the gas supplier 15. The conveyance gas is supplied into the tank 23 through the MFC 63 and introduced from the tank 23 into the chamber 11 together with the Zn-containing gas. The MFC 63 can adjust circulation and the flow rate of the Zn-containing gas by adjusting circulation and the flow rate of the conveyance gas.

As described above, the semiconductor manufacturing apparatus of the present embodiment forms the film 2 (IGZO film) containing aluminum by using the In-containing liquid containing aluminum. Thus, the present embodiment makes it possible to, for example, simplify the materials, processes, instruments, and the like for forming the film 2 and perform the processing of forming the film 2 in a short time and with fewer cycles, thereby excellently forming the film 2 including a plurality of elements.

### Second Embodiment

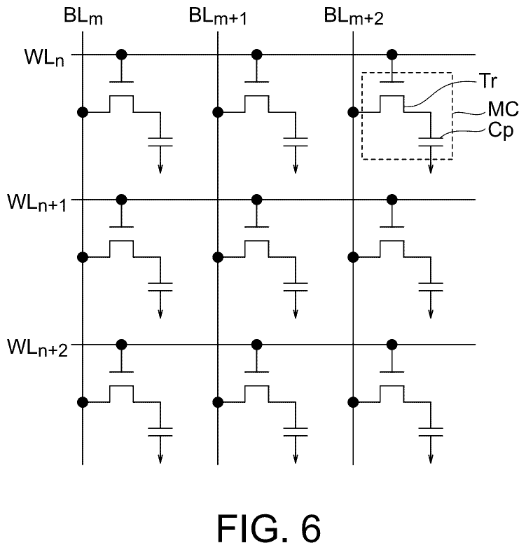

FIG. 6 is a circuit diagram illustrating the configuration of a semiconductor device of a second embodiment. The semiconductor device of the present embodiment is, for example, a dynamic random access memory (DRAM). The semiconductor device of the present embodiment corresponds to an example of the semiconductor device of the first embodiment.

The semiconductor device of the present embodiment includes a plurality of word lines WL extending in a row direction, a plurality of bit lines BL extending in a column direction, and a plurality of memory cells MC disposed in a two-dimensional array. FIG. 6 illustrates three word lines WLₙ, WLₙ₊₁, and WLₙ₊₂ (n is an integer of two or greater) as examples of the plurality of word lines WL. FIG. 6 further illustrates three bit lines BLₘ, BLₘ₊₁, and BLₘ₊₂ (m is an integer of two or greater) as examples of the plurality of bit lines BL.

Each memory cell MC includes a transistor Tr and a capacitor Cp and is disposed near an intersection point of one word line WL and one bit line BL. The gate of the transistor Tr is electrically connected to the word line WL, one of the source and drain of the transistor Tr is electrically connected to the bit line BL, and the other of the source and drain of the transistor Tr is electrically connected to the capacitor Cp. One of the electrodes of the capacitor Cp is electrically connected to the transistor Tr, and the other electrode of the capacitor Cp is electrically connected to a ground line.

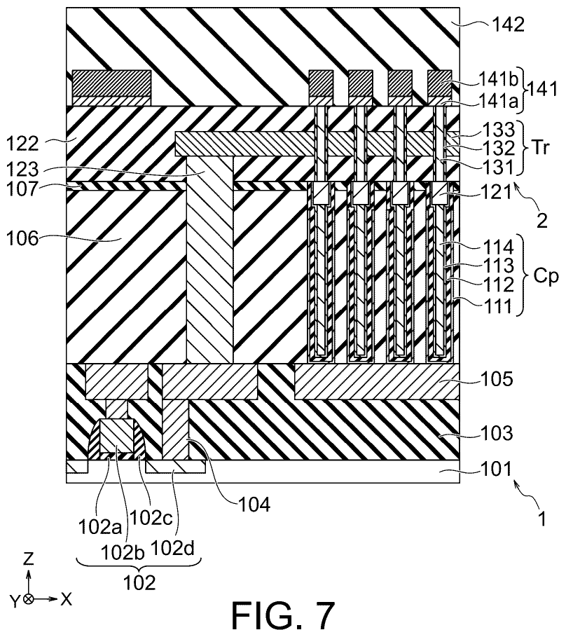

FIG. 7 is a cross-sectional view illustrating the structure of the semiconductor device of the second embodiment. FIG. 7 illustrates, as an example, a section of four transistors Tr and four capacitors Cp constituting four memory cells MC.

The semiconductor device of the present embodiment includes a substrate 101, a transistor 102, an inter layer dielectric 103, a plurality of contact plugs 104, an interconnect layer 105, an inter layer dielectric 106, and an inter layer dielectric 107. The transistor 102 includes a gate insulator 102a, a gate electrode 102b, a sidewall insulator 102c, and a source/drain region 102d.

The substrate 101 is, for example, a semiconductor substrate such as an Si substrate. In FIG. 7, the surface of the substrate 101 is parallel to the X and Y directions and orthogonal to the Z direction. The substrate 101 of the present embodiment corresponds to an example of the substrate 1 of the first embodiment.

The transistor 102 is formed on the substrate 101. The gate insulator 102a and the gate electrode 102b are sequentially formed on the substrate 101, the sidewall insulator 102c is formed on the side face of the gate electrode 102b, and the source/drain region 102d is formed in the substrate 101. The semiconductor device of the present embodiment includes a plurality of transistors 102, and FIG. 7 illustrates one of these transistors 102. These transistors 102 constitute, for example, a peripheral circuit of a DRAM.

The inter layer dielectric 103 is formed on the substrate 101 to cover the transistors 102. Each contact plug 104 is formed on the gate electrode 102b or the source/drain region 102d in the inter layer dielectric 103. The interconnect layer 105 is formed on each contact plug 104 in the inter layer dielectric 103. FIG. 7 illustrates three interconnects included in the interconnect layer 105. The inter layer dielectric 106 is formed on the inter layer dielectric 103 and the interconnect layer 105. The inter layer dielectric 107 is formed on the inter layer dielectric 106.

Each capacitor Cp of the present embodiment includes a conductive layer 111, a dielectric layer 112, a conductive layer 113, and a conductive layer 114.

The conductive layer 111, the dielectric layer 112, the conductive layer 113, and the conductive layer 114 are sequentially formed on the side and bottom faces of a concave portion formed in the inter layer dielectrics 106 and 107. The conductive layer 111 is formed on the side faces of the inter layer dielectrics 106 and 107 and the upper face of the interconnect layer 105 in the concave portion. The conductive layer 111 forms one of the electrodes of the capacitor Cp, and the conductive layers 113 and 114 form the other electrode of the capacitor Cp. The conductive layers 111, 113, and 114 are each, for example, a semiconductor layer or a metal layer. The dielectric layer 112 is, for example, an SiO₂ film.

The semiconductor device of the present embodiment further includes a conductive layer 121, an inter layer dielectric 122, and a via plug 123.

The conductive layer 121 includes a plurality of conductive layer portions disposed on the plurality of capacitors Cp. In FIG. 7, the conductive layer 121 includes four conductive layer portions, and each conductive layer portion is disposed on the conductive layers 113 and 114 of the corresponding one capacitor Cp. Each conductive layer portion is disposed in the concave portion for the corresponding one capacitor Cp.

The inter layer dielectric 122 is formed on the inter layer dielectric 107 to cover the capacitors Cp. The via plug 123 is formed on the interconnect layer 105 in the inter layer dielectrics 106, 107, and 122.

Each transistor Tr of the present embodiment includes a semiconductor layer 131, an insulating layer 132, and an electrode layer 133.

The semiconductor layer 131 is formed in a concave portion formed in the inter layer dielectric 122 with the insulating layer 132 in between. In FIG. 7, the semiconductor layer 131 is formed on one conductive layer portion of the conductive layer 121. Accordingly, the semiconductor layer 131 of each transistor Tr is electrically connected to the conductive layers 113 and 114 of the corresponding one capacitor Cp. The semiconductor layer 131 forms a channel semiconductor layer of the transistor Tr. The semiconductor layer 131 is, for example, an oxide semiconductor film such as an IGZO film. The semiconductor layer 131 of the present embodiment corresponds to an example of the film 2 of the first embodiment.

The insulating layer 132 is formed on the side face of the concave portion formed in the inter layer dielectric 122 and is formed on the side face of the semiconductor layer 131 in the concave portion. The insulating layer 132 forms a gate insulator of the transistor Tr. The insulating layer 132 is, for example, an SiO₂ film.

The electrode layer 133 is formed on the via plug 123 in the inter layer dielectric 122. In FIG. 7, the semiconductor layer 131 and the insulating layer 132 of each transistor Tr are sequentially formed on the side face of the electrode layer 133, and the electrode layer 133 forms the gate electrode of the transistor Tr. In addition, the electrode layer 133 illustrated in FIG. 7 forms one word line WL for the four transistors Tr illustrated in FIG. 7 and extends in the X direction. The electrode layer 133 is, for example, a metal layer.

The semiconductor device of the present embodiment further includes an interconnect layer 141 and an inter layer dielectric 142. The interconnect layer 141 includes a barrier metal layer 141a and an interconnect material layer 141b.

The interconnect layer 141 includes a plurality of interconnects disposed on the plurality of transistors Tr. The interconnect layer 141 illustrated in FIG. 7 includes four interconnects disposed on the four transistors Tr and another interconnect. In FIG. 7, each of the four interconnects is disposed on the semiconductor layer 131 of the corresponding one transistor Tr. The four interconnects form four bit lines BL for the four transistors Tr, respectively, and extend in the Y direction. Each interconnect in the interconnect layer 141 includes the barrier metal layer 141a and the interconnect material layer 141b sequentially stacked in the Z direction.

The inter layer dielectric 142 is formed on the inter layer dielectric 122 to cover the interconnect layer 141. The inter layer dielectric 142 is, for example, an SiO₂ film.

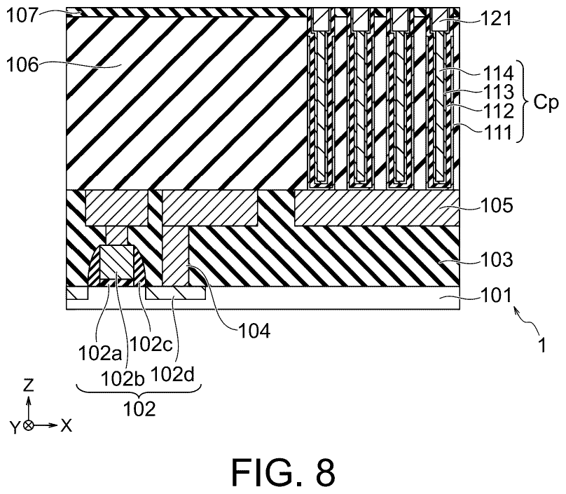

FIGS. 8 to 10 are cross-sectional views illustrating a method of manufacturing the semiconductor device of the second embodiment.

First, the substrate 101 is prepared and the transistors 102, the inter layer dielectric 103, the plurality of contact plugs 104, the interconnect layer 105, the inter layer dielectric 106, and the inter layer dielectric 107 are formed on the substrate 101 (FIG. 8).

Subsequently, the plurality of concave portions are formed in the inter layer dielectrics 106 and 107, and the plurality of capacitors Cp are formed in the concave portions (FIG. 8). Each capacitor Cp is formed by sequentially forming the conductive layer 111, the dielectric layer 112, the conductive layer 113, and the conductive layer 114 in one concave portion. The conductive layer 111 is formed on the interconnect layer 105 in the concave portion. Thereafter, the plurality of conductive layer portions of the conductive layer 121 are formed in the above-described plurality of concave portions, as well. Each conductive layer portion is formed on the conductive layers 113 and 114 in one concave portion.

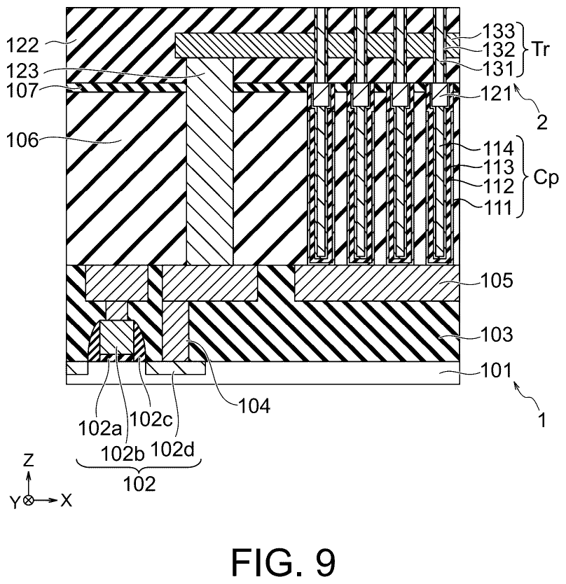

Subsequently, the inter layer dielectric 122 is formed on the inter layer dielectric 107 and the conductive layer 121, the via plug 123 is formed in the inter layer dielectrics 106, 107, and 122, and the plurality of transistors Tr are formed in the inter layer dielectric 122 (FIG. 9). Each transistor Tr is formed in the inter layer dielectric 122 to include the semiconductor layer 131, the insulating layer 132, and the electrode layer 133.

In FIG. 9, the via plug 123 is formed by forming a lower portion of the inter layer dielectric 122, forming a via hole reaching the interconnect layer 105 through the inter layer dielectric 106, the inter layer dielectric 107, and the lower portion of the inter layer dielectric 122, and forming the via plug 123 in the via hole. The electrode layer 133 is formed by forming the electrode layer 133 on the lower portion of the inter layer dielectric 122 and the via plug 123 and forming an upper portion of the inter layer dielectric 122 on the lower portion of the inter layer dielectric 122 and the electrode layer 133. In addition, the semiconductor layer 131 and the insulating layer 132 of each transistor Tr are formed by forming one concave portion in the inter layer dielectric 122 and the electrode layer 133 and sequentially forming the insulating layer 132 and the semiconductor layer 131 in the concave portion. The semiconductor layer 131 of each transistor Tr is formed on one conductive layer portion of the conductive layer 121. As a result, the semiconductor layer 131 of each transistor Tr is electrically connected to the conductive layers 113 and 114 of the corresponding one capacitor Cp. The semiconductor layer 131 of the present embodiment is formed by, for example, the same method as the film 2 of the first embodiment.

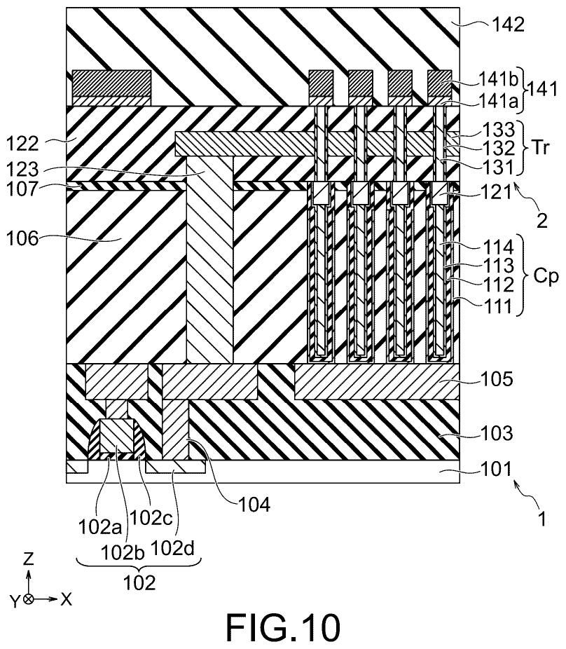

Subsequently, the interconnect layer 141 is formed on the inter layer dielectric 122 and the plurality of transistors Tr, and the inter layer dielectric 142 is formed on the inter layer dielectric 122 and the interconnect layer 141 (FIG. 10). The interconnect layer 141 is formed to include a plurality of interconnects disposed on the plurality of transistors Tr as illustrated in FIG. 10. In this manner, the semiconductor device of the present embodiment is manufactured.

The present embodiment makes it possible to excellently form the semiconductor layer 131 corresponding to an example of the film 2 of the first embodiment.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
preparing a first liquid including a first element that is a metal element or silicon, and a predetermined element that is a metal element or silicon and different from the first element;
generating a first gas including the first element and the predetermined element from the first liquid; and
forming a first film including the first element and the predetermined element on a substrate by using the first gas.

2. The method of claim 1, wherein the formation of the first film further uses a gas including oxygen.

3. The method of claim 1, wherein the predetermined element has a greater bond energy with oxygen or a smaller free energy on an Ellingham diagram than the first element.

4. The method of claim 1, wherein a concentration of the predetermined element in the first liquid is lower than a concentration of the first element in the first liquid.

5. The method of claim 1, wherein the first film is an oxide semiconductor film.

6. The method of claim 1, wherein a concentration of the predetermined element in the first liquid is 50 ppb or more.

7. The method of claim 1, wherein the first liquid is generated by adding the predetermined element to a liquid including the first element.

8. The method of claim 1, wherein the first element is indium (In), gallium (Ga), zinc (Zn), tin (Sn), antimony (Sb), aluminum (Al), silicon (Si), titanium (Ti), zirconium (Zr), hafnium (Hf), niobium (Nb), tantalum (Ta), molybdenum (Mo) or tungsten (W).

9. The method of claim 1, wherein the predetermined element is indium (In), gallium (Ga), zinc (Zn), tin (Sn), antimony (Sb), aluminum (Al), silicon (Si), titanium (Ti), zirconium (Zr), hafnium (Hf), niobium (Nb), tantalum (Ta), molybdenum (Mo) or tungsten (W).

10. The method of claim 1, further comprising:
preparing a second liquid including a second element that is a metal element or silicon and different from the first element and the predetermined element; and
generating a second gas including the second element from the second liquid,
wherein the first film including the first element, the second element, and the predetermined element is formed on the substrate by using the first gas and the second gas.

11. The method of claim 10, further comprising:
preparing a third liquid including a third element that is a metal element or silicon and different from the first element, the second element, and the predetermined element; and
generating a third gas including the third element from the third liquid,
wherein the first film including the first element, the second element, the third element, and the predetermined element is formed on the substrate by using the first gas, the second gas, and the third gas.

12. The method of claim 11, wherein each of the first element, the second element, and the third element includes indium (In), gallium (Ga) or zinc (Zn).

13. The method of claim 12, wherein the first film is an IGZO film.

14. The method of claim 12, wherein the predetermined element is aluminum (Al).

15. The method of claim 14, wherein the first film is an IGZO film including aluminum.

16. The method of claim 11, wherein the first film is formed by introducing the first gas, the second gas, and the third gas into a chamber including the substrate.

17. The method of claim 16, wherein the first film is formed by alternately repeating first processing of introducing the first gas into the chamber, second processing of introducing the second gas into the chamber, and third processing of introducing the third gas into the chamber.

18. The method of claim 11, wherein the first film is formed by:
forming a first layer including the first element and the predetermined element;
forming a second layer including the second element;
forming a third layer including the third element; and
annealing the first layer, the second layer, and the third layer to change the first layer, the second layer, and the third layer into the first film.

19. The method of claim 1, further comprising forming a transistor including the first film.

20. The method of claim 19, further comprising forming a capacitor that is electrically connected to the transistor.
